(19) United States
(12) Patent Application Publication
(10) Pub. No.: US 2004/0203213 A1
(43) Pub. Date: Oct. 14, 2004

(54) Method for manufacturing an MOS varactor

(76) Inventor: Yi-Sun Chung, Chungcheongbuk-do (KR)

Correspondence Address: MARSHALL, GERSTEIN & BORUN LLP, 6300 SEARS TOWER, 233 S. WACKER DRIVE, CHICAGO, IL, 60606, US

(21) Appl. No.: 10/789,905

(22) Filed: Feb. 27, 2004

(30) Foreign Application Priority Data
Mar. 25, 2003 (KR) 2003-18589

(51) Int. Cl. H01L 21/20; H01L 21/336

(52) U.S. Cl. 438/379; 438/197

(57) ABSTRACT

The present invention discloses a method for manufacturing an MOS varactor which can be utilized as a high frequency device with an increased capacitance of the varactor part while maintaining the characteristics of a transistor by forming a gate oxide film of the MOS varactor by a high dielectric material as compared to a gate oxide film of the transistor. The method comprises the steps of: forming a device isolation film on a semiconductor substrate; depositing a gate oxide film and a first polysilicon after the formation of the device isolation film; patterning the resultant material and etching the first polysilicon and the gate oxide film to form a transistor gate; coating the resultant material with a photoresist film, then opening a varactor forming region and then forming a varactor oxide film of a high dielectric material; depositing the second polysilicon and then patterning the same to form a varactor gate; and removing the photoersist film of the transistor forming region and then proceeding to the following processes.

### BACKGROUND OF THE INVENTION

1. Field of the Invention

The present invention relates to a method for manufacturing a MOS varactor, and more particularly, to a method for manufacturing a MOS varactor which can be utilized as a high frequency device with an increased capacitance of the varactor part while maintaining the characteristics of a transistor by forming a gate oxide film of the MOS varactor of a high dielectric material permitting a higher capacity than a gate oxide film of the transistor.

2. Description of the Related Art

Generally, a varactor is a term to describe a variable reactor. It is a two-terminal semiconductor device whose capacitance is the function of an applied voltage, and utilized for automatic frequency control of a parametric amplifier, frequency multiplier, etc.

FIGS. 1a to 1d are views sequentially illustrated for explaining the general method for manufacturing an MOS varactor.

As shown in FIG. 1a, a pad oxide film 20 and a silicon nitride film 30 are sequentially deposited over the entire surface of a semiconductor substrate 10, and, then, in order to form a device isolation film 40, a trench etching is carried out, by a mask, to form a trench hole 42.

Afterwards, as shown in FIG. 1b, the trench hole 42 is gap-filled, then planarized by a CMP process, and then the silicon nitride film 30 is removed to form a device isolation film 40.

Then, a well implantation process and a doping process for achieving various device characteristics are performed.

Then, as shown in FIG. 1c, a dielectric material such as SiO₂ or SiON is deposited as a gate oxide film 50 over the entire surface of the resultant material. And, a polysilicon 60 is deposited, a NMOS region is masked for PMOS, B or BF₂ is implanted, a PMOS region is masked for NMOS, and then P or As is implanted. Then, the polysilicon is patterned to form a transistor gate TG and a varactor gate VG.

Thereafter, as shown in FIG. 1d, spacers 70 are formed on the side walls of the transistor gate TG and of the varactor gate VG, an interlayer insulating film 80 is deposited, and then connected with wires 100 via contacts 90.

In this way, the MOS varactor is formed in the same manner as the transistor gate, so the capacity permitted by the varactor oxide film is not increased. This leads to a low capacitance per unit area, thus the varactor is restrictively adapted to a low RF device.

### SUMMARY OF THE INVENTION

The present invention is designed in consideration of the problems of the prior art, and therefore it is an object of the present invention to provide a method for manufacturing a MOS varactor which can be utilized as a high frequency device with an increased capacitance of the varactor part while maintaining the characteristics of a transistor by forming a gate oxide film of the MOS varactor of a high dielectric material having a higher capacity than a gate oxide film of the transistor.

To achieve the above object, there is provided a method for manufacturing an MOS varactor according to the present invention, comprising the steps of: forming a device isolation film on a semiconductor substrate; depositing a gate oxide film and a first polysilicon after the formation of the device isolation film; patterning the resultant material and etching the first polysilicon and the gate oxide film to form a transistor gate; coating the entire resultant material with a photoresist film, then opening a varactor forming region and then forming a varactor oxide film of a high dielectric material; depositing the second polysilicon and then patterning the same to form a varactor gate; and removing the photoersist film of the transistor forming region and then proceeding to the following process.

Additionally, there is provided a method for manufacturing a MOS varactor according to the present invention, comprising the steps of: forming a device isolation film on a semiconductor substrate; forming a varactor oxide film of a high dielectric material on the entire surface of the resultant material and then removing the regions except for the varactor to pattern the same; depositing a gate oxide film and a polysilicon on the entire surface of the resultant material and implanting ions in accordance with a MOS type; and patterning the polysilicon by a mask, patterning the transistor gate and the varactor gate and then proceeding to the following process.

Preferably, the varactor oxide film is any one of Al₂O₃, Ta₂O₅, HfO₂, ZrO₂, HfON, BST and TiO₂.

Preferably, the varactor oxide film is deposited at less than 400° C. by a deposition technique such as ALD, PEALD and MOCVD.

In the method for manufacturing a MOS varactor according to the present invention, the varactor oxide film, which is the varactor gate oxide film, is made of a dielectric material having a higher capacity than the transistor gate oxide film, thus the MOS varactor can be utilized as a high frequency device with an increased capacitance of the varactor part while maintaining the characteristics of a transistor, and can increase the margin of the device because of a high synchronization.

### BRIEF DESCRIPTION OF THE DRAWINGS

Other objects and aspects of the present invention will become apparent from the following description of embodiments with reference to the accompanying drawings in which:

FIGS. 1a to 1d are views sequentially illustrated for explaining a general method for manufacturing a MOS varactor;

FIGS. 2a to 2g are sectional views sequentially illustrated for explaining a method for manufacturing a MOS varactor according to a first embodiment of the present invention; and

FIGS. 3a to 3e are sectional views sequentially illustrated for explaining the method for manufacturing an MOS varactor according to a second embodiment of the present invention.

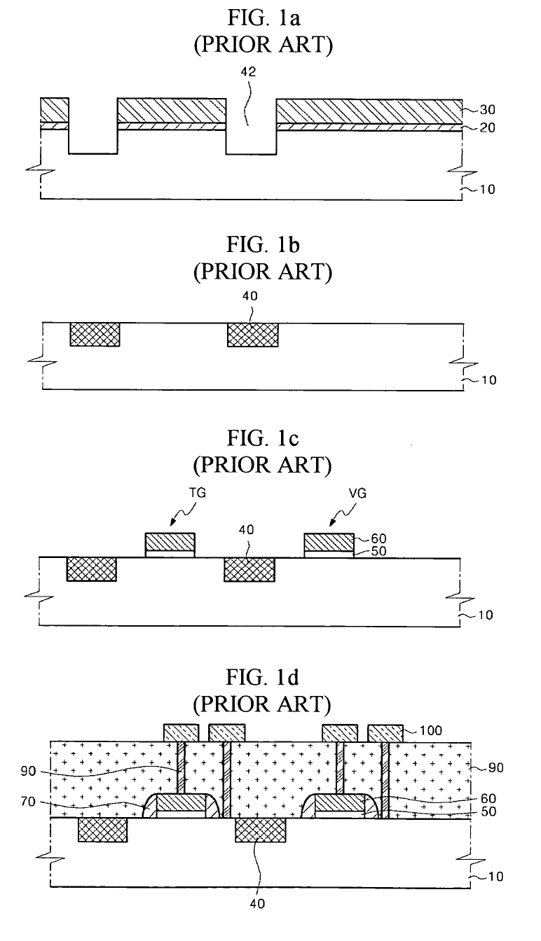

### DESCRIPTION OF THE PREFERRED EMBODIMENT

Hereinafter, preferred embodiments of the present invention will be described in more detail referring to the drawings. In addition, the following embodiments are for illustration only, not intended to limit the scope of the invention, and the identical component to the conventional art uses the identical reference numeral and name.

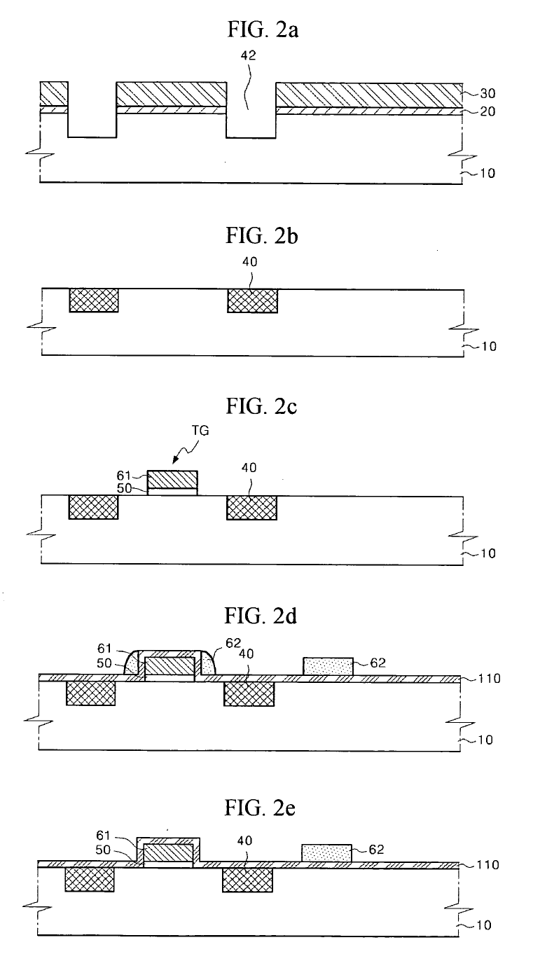

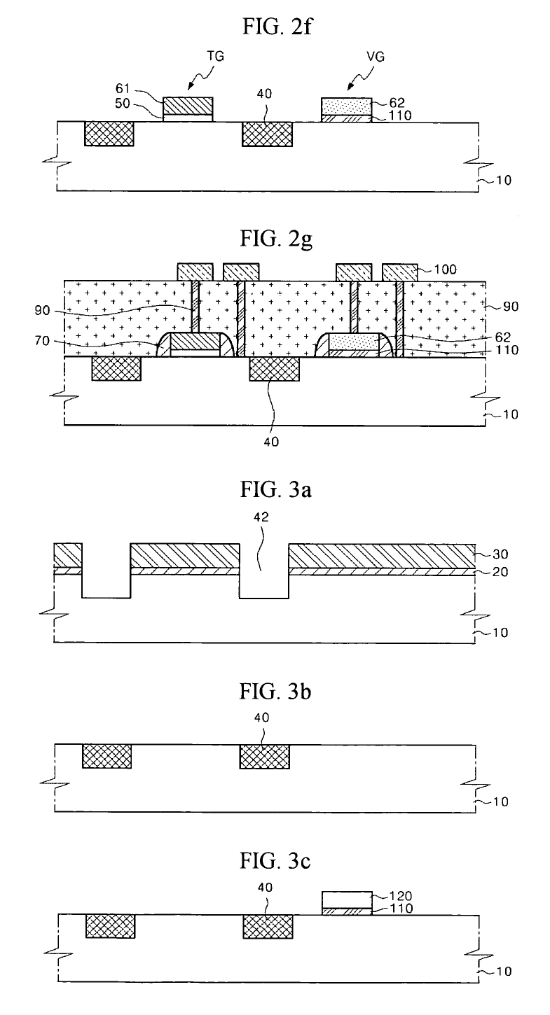

FIGS. 2a to 2g are sectional views sequentially illustrated for explaining a method for manufacturing an MOS varactor according to a first embodiment of the present invention.

Firstly, as shown in FIG. 2a, a pad oxide film 20 and a silicon nitride film 30 are sequentially deposited on the entire surface of a semiconductor substrate 10, and, then, in order to form a device isolation layer 40, trench etching is carried out by means of a mask to form a trench hole 42.

Afterwards, as shown in FIG. 2b, the trench hole 42 is gap-filled, then put onto the same plane by a CMP process, and then the silicon nitride film 30 is removed to form a device isolation film 40.

Then, a well implantation process and a doping process for various device characteristics are performed.

Then, as shown in FIG. 2c, a gate oxide film 50 and a first polysilicon 61 that are to be adapted to a transistor are sequentially deposited on the entire surface of the resultant material and patterned to form a transistor gate TG.

At this time, as the gate oxide film 50, deposited is a dielectric material such as SiO₂, SiON and the like.

Then, as shown in FIG. 2d, a varactor oxide film 110 is deposited on the entire surface of the resultant material.

At this time, as the varactor oxide film 110, any one of Al₂O₃, Ta₂O₅, HfO₂, ZrO₂, HfON, BST and TiO₂ is deposited at less than 400° C. by a deposition technique such as ALD, PEALD, MOCVD, etc. so that no change occurs in the characteristics of the transistor.

Then, a post process is carried out by a plasma treatment using O₂, O₃, N₂, NH₃, etc. or an O₃ annealing.

And, a second polysilicon 62 that is to be used for the varactor gate VG is deposited onto the deposited varactor oxide film 110, and then patterned by a mask for forming the varactor gate VG to etch the entire second polysilicon 62 except for the varactor gate VG.

When etching in this way, the varactor gate region is selectively etched to form a varactor gate VG, while the transistor forming region is blanket-etched to thus leave the second polysilicon 62 on the side walls of the transistor gate TG.

Therefore, as shown in FIG. 2e, the second polysilicon 62 remaining on the sidewalls of the transistor gate TG is removed by selective etching. As shown in FIG. 2f, the varactor oxide film 110 is selectively etched to remove the entire varactor oxide film 110 in the transistor forming region.

Thereafter, as shown in FIG. 2g, spacers 70 are formed on the side walls of the transistor gate TG and of the varactor gate VG, and an interlayer insulating film 80 is deposited and then connected with wires 100 via contacts 90.

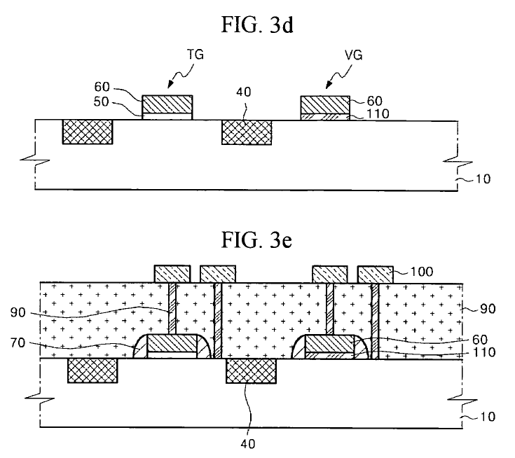

FIGS. 3a to 3e are sectional views sequentially illustrated for explaining the method for manufacturing an MOS varactor according to a second embodiment of the present invention. The present invention will be described with reference to these drawings.

Firstly, as shown in FIG. 3a, a pad oxide film 20 and a silicon nitride film 30 are sequentially deposited over the entire surface of a semiconductor substrate 10, and, then, in order to form a device isolation layer 40, a trench etching is carried out by means of a mask to form a trench hole 42.

Afterwards, as shown in FIG. 3b, the trench hole 42 is gap-filled, then put onto the same plane by a CMP process, and then the silicon nitride film 30 is removed to form a device isolation film 40.

Then, a well implantation process and a doping process for achieving various device characteristics are performed.

Then, as shown in FIG. 3c, a varactor oxide film 110 over the entire surface of the resultant material that is to be adapted to a varactor is deposited.

At this time, as the varactor oxide film 110, any one of Al₂O₃, Ta₂O₅, HfO₂, ZrO₂, HfON, BST and TiO₂ is deposited at less than 400° C. by a deposition technique such as ALD, PEALD, MOCVD, etc. so that no change occurs in the characteristics of the transistor.

Then, a photoresist film is coated over the entire surface and then patterned by a mask for forming a varactor gate VG to etch the entire varactor oxide film 110 except for the varactor gate VG.

Then, as shown in FIG. 3d, a postprocess is carried out by a plasma treatment using O₂, O₃, N₂, NH₃, etc. or an O₃ annealing, thereby increasing the density of the varactor oxide film 110 and growing a transistor gate oxide film 50 in the regions when the varactor oxide film 110 was not formed.

At this time, as the gate oxide film 50, a dielectric material such as SiO₂, SiON and the like is deposited.

Then, a polysilicon 60 is deposited, a NMOS region is masked for PMOS, B or BF₂ is implanted, a PMOS region is masked for NMOS, and then P or As is implanted. Then, the polysilicon is patterned to form a transistor gate TG and a varactor gate VG.

Thereafter, as shown in FIG. 3e, spacers 70 are formed on the side walls of the transistor gate TG and of the varactor gate VG, an interlayer insulating film 80 is deposited, and then connected with wires 100 via contacts 90.

Accordingly, as the varactor oxide film 110 is deposited with a high dielectric material, the capacitance per unit area is increased, thereby improving the characteristics of an RF device.

As explained above, according to the present invention, the MOS varactor can be utilized as a high frequency device with an increased capacitance of the varactor part while maintaining the characteristics of a transistor by forming a gate oxide film of the MOS varactor of a high dielectric material having a higher permittivity than a gate oxide film of the transistor.

What is claimed is:

1. A method for manufacturing a MOS varactor, comprising the steps of:
forming a device isolation film on a semiconductor substrate;
depositing a gate oxide film and a first polysilicon after the formation of the device isolation film;
patterning the resultant material and etching the first polysilicon and the gate oxide film to form a transistor gate;
coating the entire resultant material with a photoresist film, then opening a varactor forming region and then forming a varactor oxide film of a high dielectric material;
depositing the second polysilicon and then patterning the same to form a varactor gate; and
removing the photoersist film of the transistor forming region and then proceeding to the following process.

2. A method for manufacturing a MOS varactor, comprising the steps of:
forming a device isolation film on a semiconductor substrate;
forming a varactor oxide film of a high dielectric material over the entire surface of the resultant material and then removing the regions except for the varactor to pattern the same;
depositing a gate oxide film and a polysilicon on the entire surface of the resultant material and implanting ions in accordance with an MOS type; and
patterning the polysilicon by a mask, patterning the transistor gate and the varactor gate and then proceeding to the following process.

3. The method of claim 1, wherein the varactor oxide film is selected from the group consisting of Al₂O₃, Ta₂O₅, HfO₂, ZrO₂, HfON, BST and TiO₂.

4. The method of claim 1, wherein the varactor oxide film is deposited at less than 400° C. by a deposition technique selected from the group consisting of ALD, PEALD and MOCVD.

5. The method of claim 2, wherein the varactor oxide film is selected from the group consisting of Al₂O₃, Ta₂O₅, HfO₂, ZrO₂, HfON, BST and TiO₂.

6. The method of claim 2, wherein the varactor oxide film is deposited at less than 400° C. by a deposition technique selected from the group consisting of ALD, PEALD and MOCVD.
